(19) United States
(12) Patent Application Publication
(10) Pub. No.: US 2007/0217162 A1
(43) Pub. Date: Sep. 20, 2007

(54) HEAT DISSIPATION DEVICE

(75) Inventors: Shi-Wen Zhou, Shenzhen (CN); Chun-Chi Chen, Tu-Cheng (TW); Zhan Wu, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Taipei Hsien (TW)

(21) Appl. No.: 11/309,758

(22) Filed: Sep. 22, 2006

(30) Foreign Application Priority Data
Mar. 17, 2006 (CN) 200610034545.X

(51) Int. Cl. H05K 7/20

(52) U.S. Cl. 361/710

(57) ABSTRACT

A heat dissipation device includes a heat sink and a back plate assembly thermally independent from the sink. The back plate assembly includes a body facing a bottom surface of the heat sink and a heat-dissipating member thermal connecting to the body. The heat sink is used for absorbing heat generated by a heat-generating electronic component from a top side thereof. The back plate assembly is used for absorbing the heat generated by the heat-generating electronic component from a bottom side thereof. The heat sink and the back plate assembly are connected together by fixing members extending from the heat sink through a printed circuit board on which the electronic component is mounted to threadedly engage with the back plate assembly.

### FIELD OF THE INVENTION

The present invention relates to a heat dissipation device, more particularly to a heat dissipation device with a better heat dissipating capability.

### DESCRIPTION OF RELATED ART

As computer technology continues to advance, electronic components such as the central processing units (CPUs) of computers are being made to provide faster operational speeds and greater functional capabilities. When a CPU operates at high speed in a computer enclosure, its temperature usually increases enormously. It is therefore desirable to dissipate the generated heat of the CPU quickly before damage is caused. Usually, a heat dissipation device is held in thermal contact with the CPU.

A conventional heat dissipation device commonly includes a base mounted on a top of a CPU mounted on a printed circuit board, and a plurality of fins vertically extending from the base. To provide excellent heat dissipation effect, the heat dissipation device is designed to have, generally, a large heat dissipating surface area. The bigger the heat dissipating surface area is, the higher the heat dissipation efficiency that can be obtained. This generally leads to an increase of the volume of the heat dissipation device. However, due to space limitations in modern computers, the heat dissipation device cannot be made too large. Moreover, the bigger the heat dissipation device is, the heavier the heat dissipation device will be. As a result, the heat dissipation device will exert a larger force on the printed circuit board due to its heavy weight. Such a heavy weight may lead to a deformation of the printed circuit board.

What is needed, therefore, is a heat dissipation device, which can overcome the above-described disadvantages.

### SUMMARY OF THE INVENTION

A heat dissipation device comprises a heat sink and a back plate assembly thermally independent from the heat sink. The back plate assembly comprises a body facing a bottom surface of the heat sink and a heat-dissipating member thermally connected to the body. The heat sink and the back plate assembly are mounted to opposite sides of a heat-generating electronic component, whereby heat generated by the electronic component can be simultaneously dissipated to ambient environment by the heat sink and the back plate assembly.

Other advantages and novel features will become more apparent from the following detailed description of preferred embodiments when taken in conjunction with the accompanying drawings, in which:

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded view of a heat dissipation device in accordance with a preferred embodiment, together with an electronic component and a printed circuit board;

FIG. 2 is an enlarged isometric view of a back plate assembly of the heat dissipation device of FIG. 1, viewed from another aspect; and

FIG. 3 is an assembled view of FIG. 1; and

FIG. 4 is an isometric view of a back plate assembly of a heat dissipation device in accordance with another embodiment.

### DETAILED DESCRIPTION OF THE INVENTION

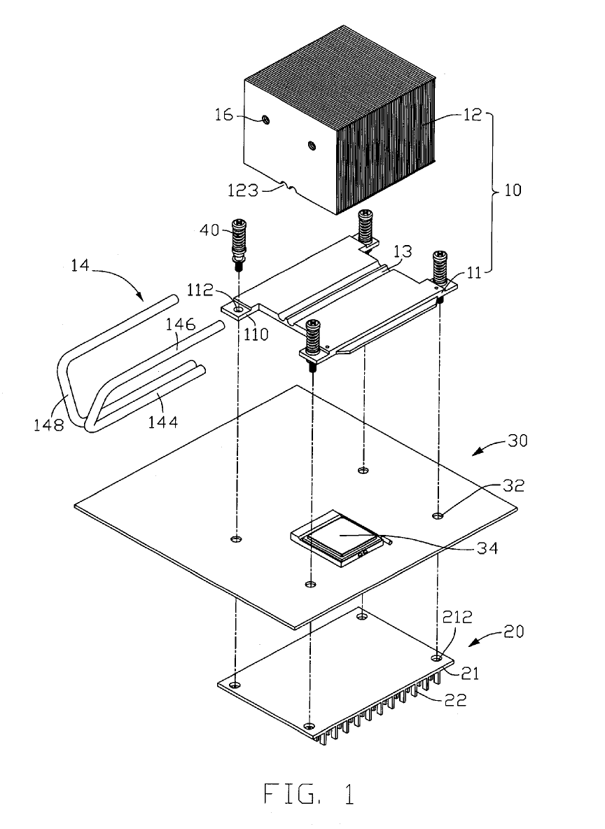

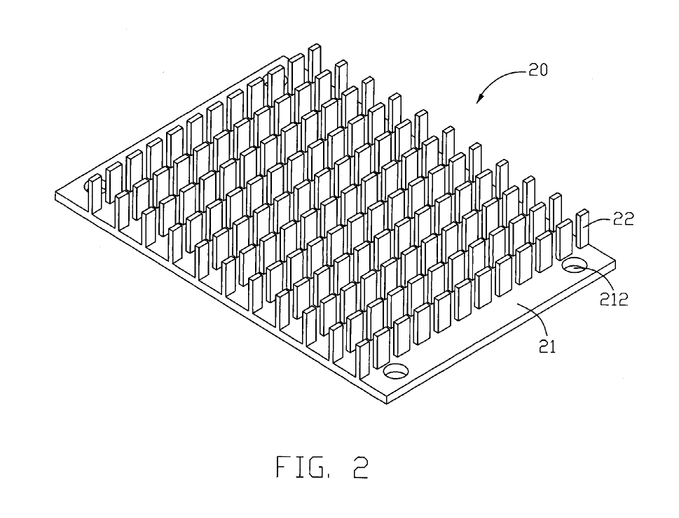

Referring to FIGS. 1-3, a heat dissipation device in accordance with a first preferred embodiment is illustrated. The heat dissipation device comprises a heat sink 10 mounted on a top surface of a printed circuit board 30, a back plate assembly 20 attached to a bottom surface of the printed circuit board 30, and a plurality of fixing members 40, such as screws with springs co-axially mounted thereon. The screws extend through the springs, the heat sink 10 and the printed circuit board 30 to engage with the back plate assembly 20, so as to secure the heat sink 10 and the back plate assembly 20 on opposite top and bottom surfaces of the printed circuit board 30.

In this embodiment, a CPU 34, to be cooled, is positioned on the top surface of the printed circuit board 30, and the printed circuit board 30 defines four through holes 32 around the CPU 34 for the screws extending therethrough. The arrangement of the through holes 32 is determined by the relative position of the CPU 34 and the heat sink 10.

The heat sink 10 is merely dissipated heat originated from the CPU 34 via the space located above the printed circuit board 30. The heat sink 10 comprises a substantially rectangular base 11, a plurality of fins 12 vertically extending from the base 11, and two heat pipes 14.

The base 11 is made of heat conductive material, such as copper or aluminum, and has a flat bottom surface for contacting with the CPU 34. Each corner of the base 11 has an ear 110 formed thereon, and each ear 110 defines an aperture 112 therein aligning with the corresponding through hole 32 of the printed circuit board 30. Two parallel grooves 13 are defined in a top portion of a middle of the base 11, facing towards a bottom surface of the fins 12.

The bottom surface of the fins 12 defines two grooves 123, and the grooves 123 of the fins 12 cooperate with the corresponding grooves 13 of the base 11 to form two passages. Near a top portion of the fins 12, two parallel channels 16 are defined through the fins 121. A distance between the two channels 16 of the fins 12 is larger than that between the grooves 123 of the fins 12.

The heat pipes 14 are substantially U-shaped, and each comprises a first heat transferring portion 144, a second heat transferring portion 146 and a third heat transferring portion 148 interconnecting the first heat transferring portion 144 and the second transferring portion 146.

The first heat transferring portions 144 of the heat pipes 14 are received in the corresponding channels cooperatively defined by the base 11 and the fins 10, to absorb heat from the base 11; thus, the first heat transferring portions 144 of the heat pipes 14 serve as evaporators. The second heat transferring portions 146 of the heat pipes 14 are retained in the corresponding channels 16 of the fins 12, and used for dissipating the absorbed heat to the fins 12; thus, second heat transferring portions 146 of the heat pipes 14 serve as condensers. The third heat transferring portion 148 are disposed at one side of the fins 12. The heat absorbed by the first heat transferring portions 144 is upwardly transferred to the second heat transferring portions 146 along the third heat transferring portions 148.

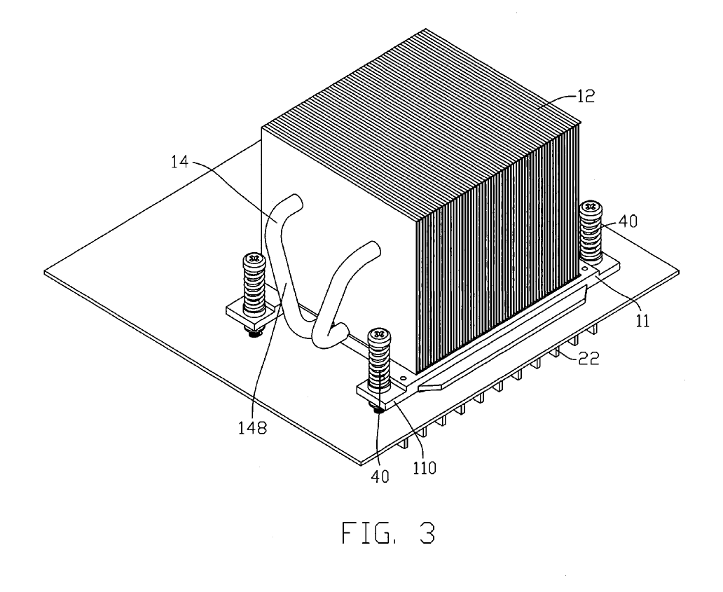

As shown in FIG. 3, after the heat pipes 14 are assembled to the fins 12 and the base 11, a distance between the second heat transferring portions 146 is larger than that between the first heat transferring portions 144. This serves to evenly and uniformly spread the heat over the whole fins 12 via the second heat transferring portions 146.

When the heat sink 10 is positioned on the top surface of the CPU 34, the heat sink 10 will exert a downward force on the printed circuit board 30 due to a weight of the heat sink 10. To reinforce the printed circuit board 30, the back plate assembly 20 is used to bear the weight of the heat sink 10.

In additional to support the printed circuit board 30, the back plate assembly 20 also utilizes the space below the printed circuit board 30 to dissipate a part of the heat originated from the CPU 34. The back plate assembly 20 comprises a body 21 tightly abutting against the bottom surface of the printed circuit board 30, and a heat-dissipating member below the body 21. Four threaded holes 212 are respectively defined in four corners of the body 21, and aligned with the through holes 32 of the printed circuit board 30 to engage with the threaded portions of the screws of the fixing members 40. By the engagement of the screws and the threaded holes 212 of the back plate assembly 20, the heat sink 10 and the back plate assembly 20 are assembled together, whereby the printed circuit board 30 is sandwiched therebetween.

During operation, part of the heat originating from the CPU 34 is conducted downwards to the body 21 of the back plate assembly 20 through the printed circuit board 30, and then the heat is dissipated via the heat-dissipating member. Therefore, the back plate assembly 20 can utilize the space below the printed circuit board 30 to dissipate the heat. This serves to increase the total heat-dissipating surface of the heat dissipation device, and the heat dissipation efficiency of the heat dissipation device is improved.

In this embodiment, the heat-dissipating member comprises a plurality of heat dissipating plates 22 integrally and downwards extending from the body 21 of the back plate assembly 20. Alternatively, the heat dissipating plates 22 may be individually manufactured before being attached to the body 21 of the back plate assembly 20.

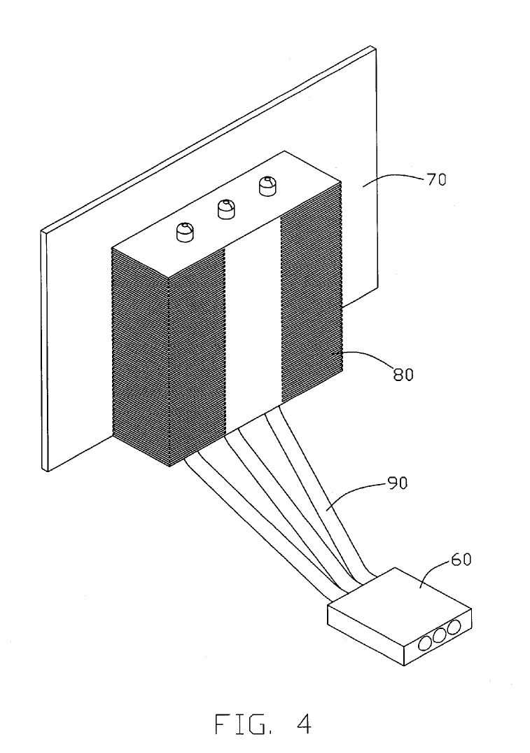

In a further embodiment shown in FIG. 4, the back plate assembly comprises a body 60, a heat-dissipating member 80, and three heat pipes 90. The heat-dissipating member 80 is thermally connected to the body 60 through the heat pipes 90. Each heat pipe 90 has an evaporator (not labeled) thermally contacting the body 60 and a condenser (not labeled) inserted into the heat-dissipating member 80. The body 60 has a same function to the body 21 of FIG. 1, and is attached to the bottom surface of the printed circuit board 30 in the same manner as described above in respect to the body 21, or in any conventional manner.

Part of the heat originated from the CPU 34 is downwards transferred to the body 60 through the printed circuit board 30. The heat is then transferred to the heat-dissipating member 80 via the heat pipes 90 to be dissipated. The heat-dissipating member 80 is positioned at a place appropriate for heat dissipation, which has a lower temperature or a larger space to increase the heat dissipating efficiency of the heat dissipation device. In this embodiment, the heat-dissipating member 80 is attached to a side plate 70 of a computer enclosure, within which the CPU 34 and the printed circuit board 30 are mounted.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device, comprising:
a heat sink adapted to be mounted on a first side of a heat-generating electronic component; and
a back plate assembly thermally independent from the heat sink, adapted to be mounted on a second side of the heat-generating electronic component opposite from the first side, the back plate assembly comprising a body facing a bottom surface of the heat sink and a heat-dissipating member thermally connected to the body.

2. The heat dissipate on device as claimed in claim 2, further comprising a plurality of fixing members extending through the heat sink to be engaged with the body.

3. The heat dissipation device as claimed in claim 1, wherein the heat-dissipating member comprises a plurality of heat-dissipating plates extending from the body along a direction away from the heat sink.

4. The heat dissipation device as claimed in claim 1, further comprising a heat pipe thermally connecting the heat-dissipating member to the body.

5. The heat dissipation device as claimed in claim 1, wherein the heat sink comprises a base and a plurality of fins extending from the base along a direction away from the body of the back plate assembly.

6. The heat dissipation device as claimed in claim 5, wherein the heat sink further comprises a heat pipe thermally connecting the base to the fins.

7. The heat dissipation device as claimed in claim 6, wherein the heat pipe comprises a first heat transferring portion sandwiched between the base and the fins, and a second heat transferring portion inserted into the fins.

8. The heat dissipation device as claimed in claim 7, further comprising another heat pipe thermally connecting the heat-dissipating member to the body.

9. The heat dissipation device as claimed in claim 8, wherein the another heat pipe has an evaporator thermally contacting the body and a condenser thermally contacting the heat-dissipating member.

10. An electronic package, comprising:
a printed circuit board with an electronic component mounted on a top side thereof; and
a heat dissipation device comprising:
a heat sink mounted on the top side of the printed circuit board and thermally contacting the electronic component for receiving heat from the electronic component;
a back plate assembly comprising a body attached to a bottom side of the printed circuit board to receive the heat from the electronic component via the printed circuit board and a heat-dissipating member thermally coupled to the body;
a plurality of fixing members extending though the heat sink, the printed circuit board and engaging with the body of the back plate assembly to position the back plate assembly and the heat sink to the printed circuit board.

11. The electronic package as claimed in claim 10, wherein the heat-dissipating member comprises a plurality of heat-dissipating plates extending from the body along a direction away from the heat sink.

12. The electronic package as claimed in claim 10, further comprising a heat pipe thermally connecting the heat-dissipating member to the body.

13. The electronic package as claimed in claim 10, wherein the heat sink comprises a base contacting the electronic component and a plurality of fins mounted on the base.

14. The electronic package as claimed in claim 13, wherein the heat sink further comprises a heat pipe having a first heat transferring portion embedded in the base and a second heat transferring portion extending into the fins.

15. The electronic package as claimed in claim 14, further comprising another heat pipe which has an evaporator thermally contacting the body and a condenser thermally engaging with the heat-dissipating member.

16. The electronic package as claimed in claim 11, wherein the body of the back plate assembly has a plurality of threaded holes defined therein for engaging with the fixing members.
